(19) United States
(12) Patent Application Publication
(10) Pub. No.: US 2025/0057028 A1
(43) Pub. Date: Feb. 13, 2025

(54) METHOD OF PRODUCTION OF LIGHT EMITTING CHIPS, LIGHT EMITTING CHIP, EXPOSURE HEAD, AND IMAGE FORMING APPARATUS

(71) Applicant: CANON KABUSHIKI KAISHA, Tokyo (JP)

(72) Inventor: YUSUKE KAMATA, Tokyo (JP)

(21) Appl. No.: 18/788,866

(22) Filed: Jul. 30, 2024

(30) Foreign Application Priority Data
Aug. 10, 2023 (JP) 2023-131464

(51) Int. Cl. H10K 71/00; H10K 59/18; H10K 59/95

(52) U.S. Cl. CPC H10K 71/851; H10K 59/18; H10K 59/95

(57) ABSTRACT

A method of production of light emitting chips to be used in an exposure head of an image forming apparatus, the method comprising: thinning a wafer having a first surface on which a plurality of light emitting chips is formed with a scribing region acting as a spacing therebetween by grinding a second surface thereof that is a surface opposite to the first surface, each of the plurality of light emitting chips including a plurality of light emitting units that is arrayed along a predetermined direction and emit light to which a photosensitive member is exposed; forming a modified layer inside the wafer by projecting laser light toward the scribing region from the second surface so that the laser light is focused inside the wafer; and dicing the wafer along the modified layer in the scribing region into the light emitting chips.

### BACKGROUND OF THE INVENTION

### Field of the Invention

The present invention relates to a method of production of light emitting chips, a light emitting chip, an exposure head, and an image forming apparatus.

### Description of the Related Art

An image forming apparatus based on an electrophotographic method forms an electrostatic latent image on a photosensitive member, which is driven to rotate, by exposing the photosensitive member to light, and forms an image by developing this electrostatic latent image using toner. In particular, an exposure apparatus of a solid-state exposure type, which forms an image of light from a light emitting element array on the surface of a photosensitive member using a rod lens array, is drawing attention because it can be easily reduced in size, improved in quietness, and lowered in cost compared to an exposure apparatus of a laser scanning type.

Regarding an exposure apparatus of a solid-state exposure type, as it is difficult to produce a long, monolithic light emitting chip, a method is used that secures a sufficient image formation width in the axial direction of a photosensitive member by joining together a plurality of light emitting chips. Furthermore, arranging the plurality of light emitting chips in a zig-zag manner can realize an image forming region that is seamless at a joint between the light emitting chips. When the light emitting chips are arranged in a zig-zag manner, the light take-up efficiency of a rod lens array is improved by bringing the light emitting chip in the first column as close as possible to the light emitting chip in the second column. However, in the case of light emitting chips that have been cut out from a wafer, a margin having a large distance from cutout lines remains (hereinafter referred to as a scribing region).

In view of this, techniques to reduce a scribing region have been suggested. For example, according to the techniques described in Japanese Patent Laid-Open No. 2014-192339 and Japanese Patent Laid-Open No. 2023-032215, laser light is focused inside a wafer, and a modified layer is formed in the wafer at a position on which the laser light is focused. Furthermore, according to these techniques, a plurality of modified layers is formed along the thickness direction of the wafer, and the wafer is separated along the modified layers.

In mapping chips on a wafer, it is common to secure a large scribing region when cutting out light emitting chips from a wafer in consideration of operational tolerances of a processing apparatus. However, if a large scribing region is secured in an exposure head in which light emitting chips are arranged in a zig-zag manner, a problem arises where a large excess region that is not relevant to light emitting elements exists around the outer peripheries of the light emitting chips.

### SUMMARY OF THE INVENTION

According to one aspect of the present disclosure, there is provided a method of production of light emitting chips to be used in an exposure head of an image forming apparatus, the method comprising: thinning a wafer having a first surface on which a plurality of light emitting chips is are formed with a scribing region acting as a spacing therebetween by grinding a second surface thereof that is a surface opposite to the first surface, each of the plurality of light emitting chips including a plurality of light emitting units that is are arrayed along a predetermined direction and emit light to which a photosensitive member is exposed; forming a modified layer inside the wafer by projecting laser light toward the scribing region from the second surface so that the laser light is focused inside the wafer; and dicing the wafer along the modified layer in the scribing region into the light emitting chips.

According to another aspect of the present disclosure, there is provided a light emitting chip to be used in an exposure head of an image forming apparatus, the light emitting chip being produced by thinning a wafer having a first surface on which a plurality of light emitting chips is formed with a scribing region acting as a spacing therebetween by grinding a second surface thereof that is a surface opposite to the first surface, each of the plurality of light emitting chips including a plurality of light emitting units that is arrayed along a predetermined direction and emit light to which a photosensitive member is exposed; forming a modified layer inside the wafer by projecting laser light toward the scribing region from the second surface so that the laser light is focused inside the wafer; and dicing the wafer along the modified layer in the scribing region into the light emitting chips.

According to another aspect of the present disclosure, there is provided an exposure head, comprising: a light emitting chip produced by thinning a wafer having a first surface on which a plurality of light emitting chips is formed with a scribing region acting as a spacing therebetween by grinding a second surface thereof that is a surface opposite to the first surface, each of the plurality of light emitting chips including a plurality of light emitting units that is arrayed along a predetermined direction and emit light to which a photosensitive member is exposed, forming a modified layer inside the wafer by projecting laser light toward the scribing region from the second surface so that the laser light is focused inside the wafer, and dicing the wafer along the modified layer in the scribing region into the light emitting chips; and a substrate on which the light emitting chip has been mounted.

According to another aspect of the present disclosure, there is provided an image forming apparatus, comprising: an exposure head including a light emitting chip produced by thinning a wafer having a first surface on which a plurality of light emitting chips is formed with a scribing region acting as a spacing therebetween by grinding a second surface thereof that is a surface opposite to the first surface, each of the plurality of light emitting chips including a plurality of light emitting units that is arrayed along a predetermined direction and emit light to which a photosensitive member is exposed, forming a modified layer inside the wafer by projecting laser light toward the scribing region from the second surface so that the laser light is focused inside the wafer, and dicing the wafer along the modified layer in the scribing region into the light emitting chips, and a substrate on which the light emitting chip has been mounted.

Further features of the present invention will become apparent from the following description of exemplary embodiments (with reference to the attached drawings).

### BRIEF DESCRIPTION OF THE DRAWINGS

FIG. 1 is a configuration diagram showing a schematic configuration of an image forming apparatus according to an embodiment.

FIG. 2A is a diagram illustrating the configurations of a photosensitive member and an exposure head according to an embodiment.

FIG. 2B is a perspective view of the configurations of the photosensitive member and the exposure head according to an embodiment.

FIG. 3A is a diagram illustrating a configuration of a printed substrate in the exposure head according to an embodiment, as viewed from the connector side.

FIG. 3B is a diagram illustrating the configuration of the printed substrate in the exposure head according to an embodiment, as viewed from the light emitting element array side.

FIG. 4 is a diagram illustrating a light emitting chip and a light emitting element array inside the light emitting chip according to an embodiment.

FIG. 5 is a plan view showing a schematic configuration of a light emitting chip according to an embodiment.

FIG. 6 is a cross-sectional view showing a schematic configuration of a light emitting chip according to an embodiment.

FIG. 7 is a circuit diagram showing a control configuration of an exposure apparatus according to an embodiment.

FIG. 8 is a signal chart related to an access to a register of a light emitting chip according to an embodiment.

FIG. 9 is a signal chart related to transmission of image data to a light emitting chip according to an embodiment.

FIG. 10 is a functional block diagram showing a detailed configuration of a light emitting chip according to an embodiment.

FIG. 11 is a diagram illustrating multiple exposure performed by light emitting elements that are arrayed in a staircase pattern.

FIG. 12 is a plan view of a wafer on which light emitting chips are mapped.

FIG. 13 is a diagram illustrating a wafer thinning process.

FIG. 14A is an enlarged view of light emitting chips mapped on a wafer.

FIG. 14B is a plan view of a state where light emitting chips that have been cut out from a wafer are arranged on a printed substrate.

FIG. 15A is a first explanatory diagram related to a forming process in which modified layers are formed by incident laser light.

FIG. 15B is a second explanatory diagram related to a forming process in which modified layers are formed by incident laser light.

FIG. 15C is a diagram illustrating a dicing process in which a wafer is diced along modified layers into light emitting chips.

FIG. 16A is an enlarged view of light emitting chips mapped on a wafer according to a modification example.

FIG. 16B is a plan view showing a state where light emitting chips that have been cut out from a wafer in the modification example have been arranged on a printed substrate.

FIG. 17A is an enlarged view of light emitting chips mapped on a wafer according to another modification example.

FIG. 17B is a plan view showing a state where light emitting chips that have been cut out from a wafer in another modification example have been arranged on a printed substrate.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### 1. SCHEMATIC CONFIGURATION OF IMAGE FORMING APPARATUS

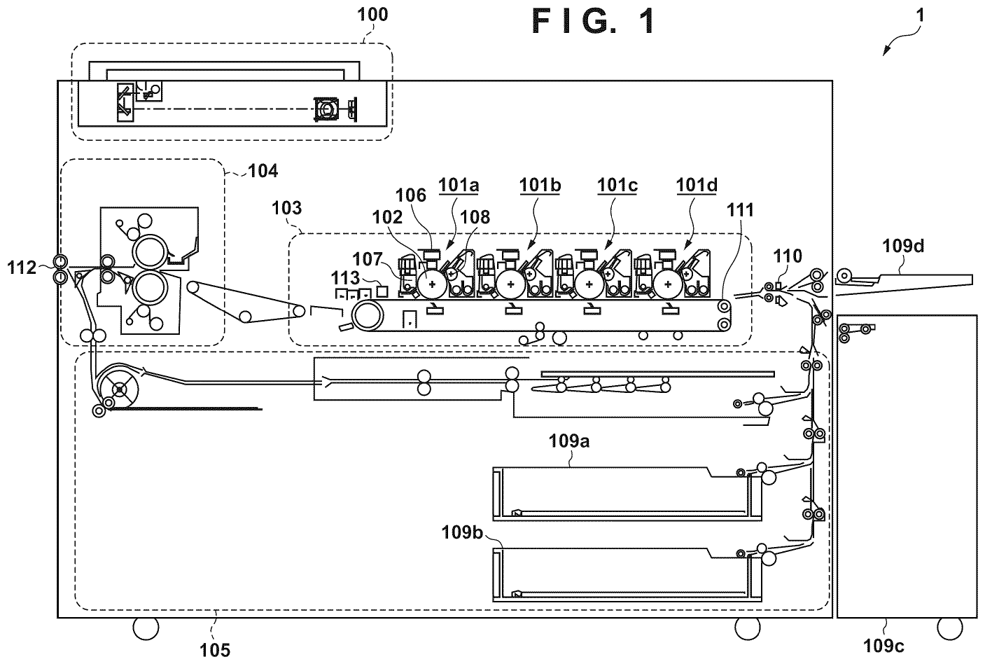

FIG. 1 shows an example of a schematic configuration of an image forming apparatus 1 according to one embodiment. The image forming apparatus 1 includes a read unit 100, an image generation unit 103, a fixing unit 104, and a conveyance unit 105. The read unit 100 optically reads a document placed on a platen, and generates read image data. The image generation unit 103 forms an image on a sheet, for example, based on the read image data generated by the read unit 100, or based on image data for printing received from an external apparatus via a network.

The image generation unit 103 includes image forming units 101a, 101b, 101c, and 101d. The image forming units 101a, 101b, 101c, and 101d respectively form toner images in black, yellow, magenta, and cyan. The image forming units 101a, 101b, 101c, and 101d are configured in a similar manner; hereinafter, they are also collectively referred to as image forming units 101. A photosensitive member 102 of an image forming unit 101 is driven to rotate in a clockwise direction of the figure at the time of image formation. A charger 107 charges the photosensitive member 102. An exposure head 106 exposes the photosensitive member 102 to light, thereby forming an electrostatic latent image on the surface of the photosensitive member 102. A developer 108 develops the electrostatic latent image on the photosensitive member 102 using toner, thereby forming a toner image. The toner image formed on the surface of the photosensitive member 102 is transferred to a sheet conveyed on a transfer belt 111. Toner images on the four photosensitive members 102 are transferred to the sheet in such a manner that they overlie one another; as a result, a color image including four color components, namely, black, yellow, magenta, and cyan, can be formed.

The conveyance unit 105 controls feeding and conveyance of sheets. Specifically, the conveyance unit 105 feeds a sheet to a conveyance path in the image forming apparatus 1 from a unit that has been designated from among internal storage units 109a and 109b, an external storage unit 109c, and a manual feed unit 109d. The sheet that has been fed is conveyed to a registration roller 110. The registration roller 110 conveys the sheet onto the transfer belt 111 at an appropriate timing so that the toner images on the respective photosensitive members 102 are transferred to the sheet. As stated earlier, the toner images are transferred to the sheet while the sheet is conveyed on the transfer belt 111. The fixing unit 104 applies heat and pressure to the sheet to which the toner images have been transferred, thereby fixing the toner images on the sheet. After the toner images have been fixed, a discharge roller 112 discharges the sheet to the outside of the image forming apparatus 1. An optical sensor 113 is arranged at a position opposing the transfer belt 111. The optical sensor 113 optically reads a test chart that has been formed on the transfer belt 111 by the image forming units 101. Upon detection of a positional displacement of the test chart that has been read by the optical sensor 113, an image controller 700, which will be described later, performs control for compensating for the positional displacement when a job is executed later.

Note that although the above has described an example in which the toner images are transferred from the respective photosensitive members 102 directly to the sheet on the transfer belt 111, the toner images may be transferred from the respective photosensitive members 102 indirectly to the sheet via an intermediate transfer member. Furthermore, although the above has described an example in which a color image is formed using toner in a plurality of colors, the technique according to the present disclosure is also applicable to an image forming apparatus that forms a monochrome image using toner in a single color.

### 2. EXEMPLARY CONFIGURATION OF EXPOSURE HEAD

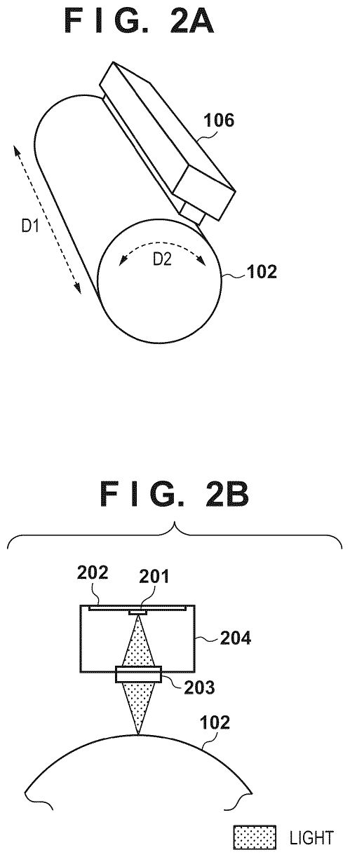

FIG. 2A and FIG. 2B show a photosensitive member 102 and an exposure head 106. The exposure head 106 includes a light emitting element array 201, a printed substrate 202 on which the light emitting element array 201 is mounted, a rod lens array 203, and a housing 204 that holds the rod lens array 203 and the printed substrate 202. The photosensitive member 102 has a cylindrical shape. The exposure head 106 is arranged so that a longitudinal direction thereof is parallel to an axial direction D1 of the photosensitive member 102, and a surface thereof to which the rod lens array 203 is attached opposes the surface of the photosensitive member 102. While the photosensitive member 102 is rotating in a circumferential direction D2, the light emitting element array 201 of the exposure head 106 emits light, and the rod lens array 203 focuses this light onto the surface of the photosensitive member 102.

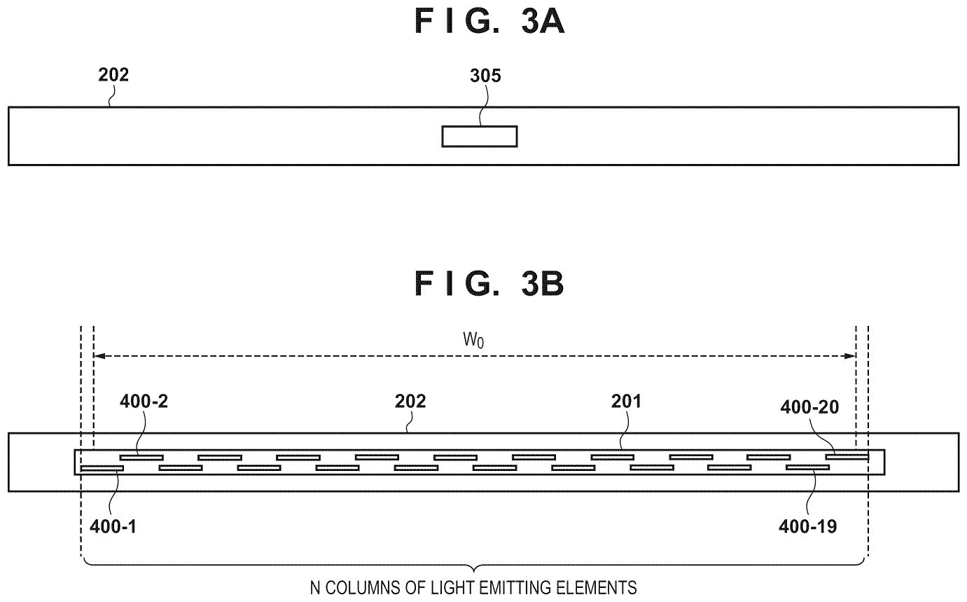

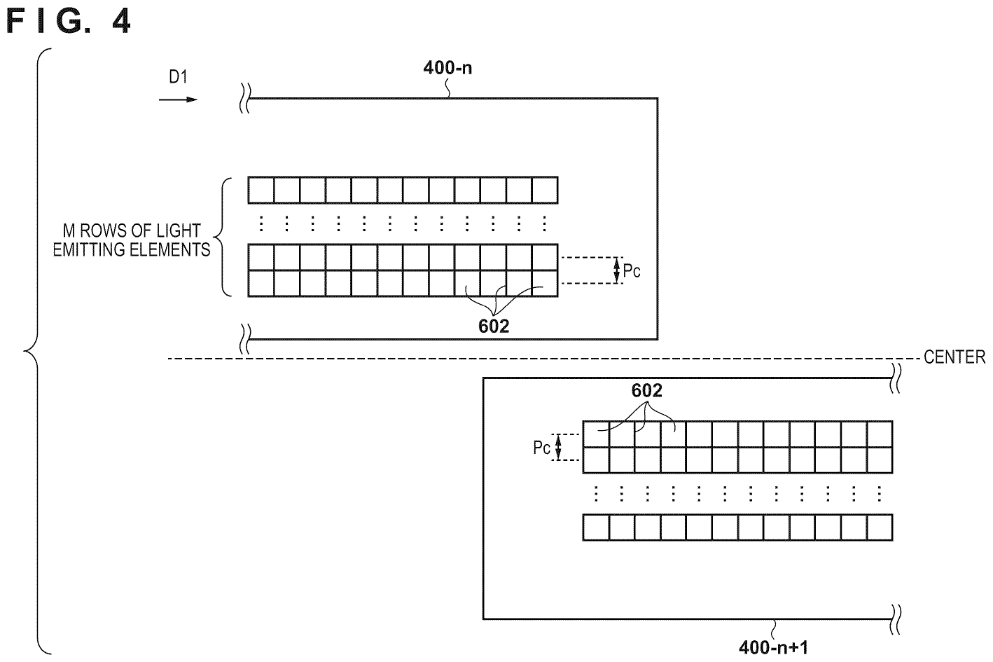

FIG. 3A and FIG. 3B show an example of a configuration of the printed substrate 202. Note that FIG. 3A shows a surface on which a connector 305 is mounted, and FIG. 3B shows a surface on which the light emitting element array 201 is mounted (a surface opposite to the surface on which the connector 305 is mounted). FIG. 4 schematically shows a light emitting chip 400, and an array of light emitting elements 602 inside the light emitting chip 400.

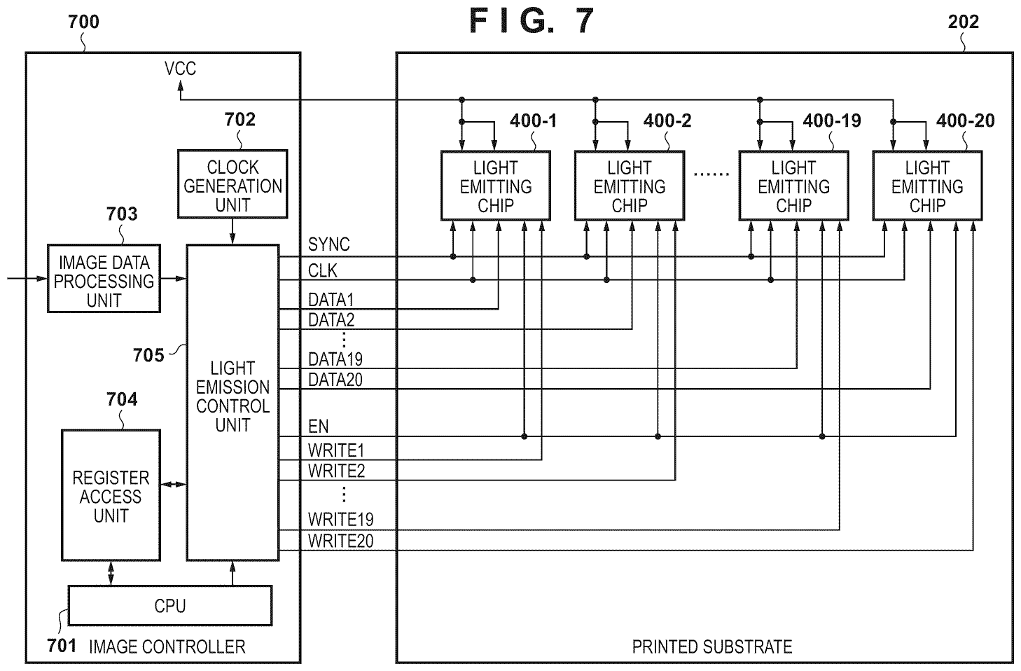

In the present embodiment, the light emitting element array 201 includes a plurality of light emitting elements that have been arrayed two-dimensionally. The light emitting element array 201, as a whole, includes N columns of light emitting elements in the axial direction D1 of the photosensitive member and M rows of light emitting elements in the circumferential direction D2 of the photosensitive member; here, M and N are integers equal to or larger than two. In the example of FIG. 3B, the light emitting element array 201 is configured in such a manner that it is divided into twenty light emitting chips 400-1 to 400-20 that each include a subset of light emitting elements included in the entirety of the plurality of light emitting elements, and the light emitting chips 400-1 to 400-20 are arranged in such a manner that they are arrayed in a zig-zag manner along the axial direction D1. The light emitting chips 400-1 to 400-20 may also be collectively referred to as light emitting chips 400. As shown in FIG. 3B, the range occupied by all of the light emitting elements in the twenty light emitting chips in the axial direction D1 is larger than the range occupied by the maximum width Wo of input image data. Therefore, some light emitting elements positioned at both ends in the axial direction D1 may not be used to expose the photosensitive member 102 to light, unless a positional displacement of an image is detected. Each light emitting chip 400 on the printed substrate 202 is connected to the image controller 700 (FIG. 7) via the connector 305. Note that hereinafter, for the sake of explanation, the side corresponding to a small branch number of the light emitting chips 400-1 to 400-20, which are arrayed along the axial direction D1, may be referred to as “left”, and the side corresponding to a large branch number thereof may be referred to as “right”. For example, the light emitting chip 400-1 is the leftmost light emitting chip 400, and the light emitting chip 400-20 is the rightmost light emitting chip.

The number J (J=N/20) of light emitting elements 602 arrayed in each row in one light emitting chip 400 may be equal to, for example, 748 (J=748). On the other hand, the number M of light emitting elements 602 arrayed in each column in one light emitting chip 400 may be equal to, for example, 4 (M=4). That is to say, in an exemplary embodiment, each light emitting chip 400 includes 748 light emitting elements 602 in the axial direction D1 and 4 light emitting elements 602 in the circumferential direction D2, which total 2992 (=748×4) light emitting elements 602. An interval Pc between the central points of light emitting elements 602 that neighbor each other in the circumferential direction D2 may be, for example, approximately 21.16 μm that corresponds to a resolution of 1200 dpi. An interval between the central points of light emitting elements 602 that neighbor each other in the axial direction D1 may also be approximately 21.16 μm; in this case, 748 light emitting elements 602 take up a length of approximately 15.8 mm in the axial direction D1. Note that although FIG. 4 shows an example in which the light emitting elements 602 are arrayed in a complete grid-like pattern in each light emitting chip 400 for the sake of explanation, M (M=4) light emitting elements 602 in each row are arrayed in a staircase pattern in reality. In this regard, a further description will be provided later.

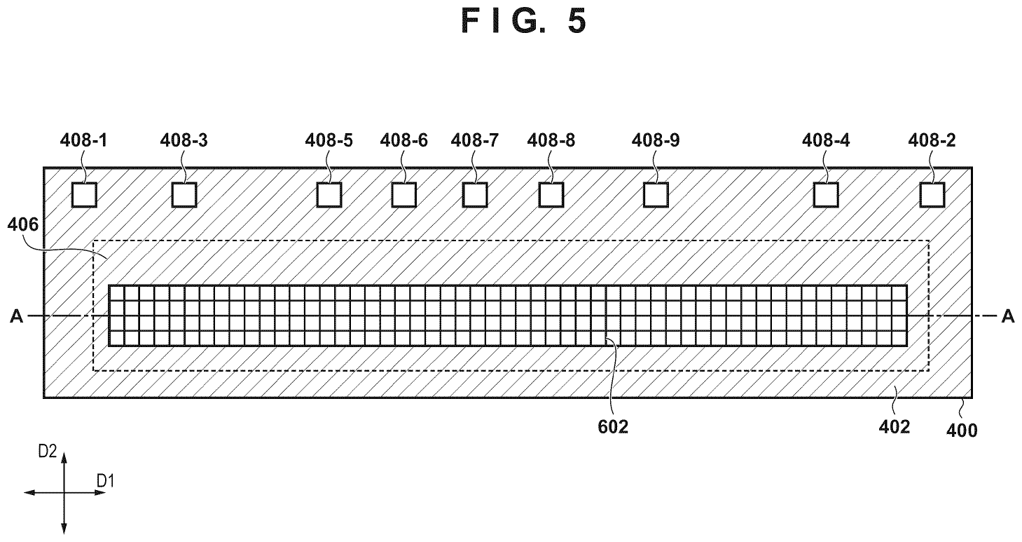

FIG. 5 is a plan view showing a schematic configuration of the light emitting chips 400. In each light emitting chip 400, the plurality of light emitting elements 602 is formed on a light emitting substrate 402 that is, for example, a silicon substrate. Also, a circuit unit 406 for driving the plurality of light emitting elements 602 is provided on the light emitting substrate 402. Signal lines for communicating with the image controller 700, power source lines for connecting to a power source, and ground lines for connecting to the ground are connected to pads 408-1 to 408-9. The signal lines, power source lines, and ground lines may be, for example, gold wires.

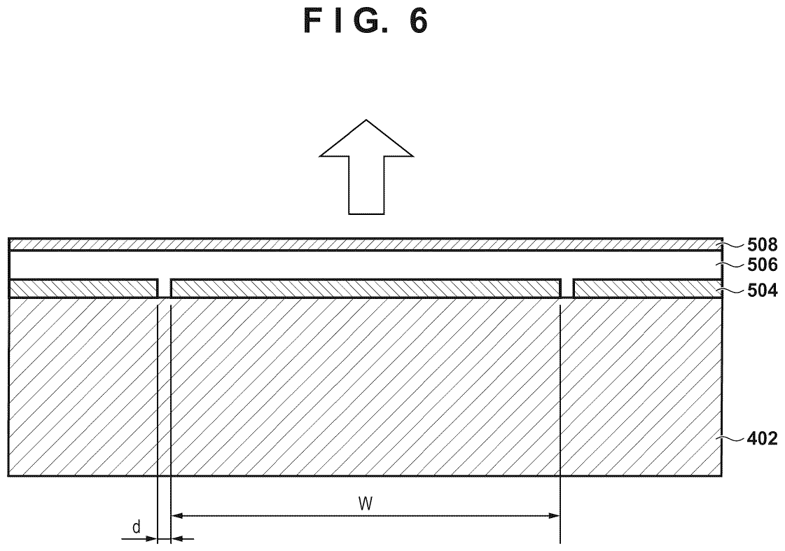

FIG. 6 shows a part of a cross-section taken along the line A-A of FIG. 5. A plurality of lower electrodes 504 is formed on the light emitting substrate 402. A gap having a width of d is provided between two neighboring lower electrodes 504. A light emitting layer 506 is provided on the lower electrodes 504, and an upper electrode 508 is provided on the light emitting layer 506. The upper electrode 508 is one common electrode for the plurality of lower electrodes 504. When a voltage is applied between the lower electrodes 504 and the upper electrode 508, a current flows from the lower electrodes 504 to the upper electrode 508, thereby causing the light emitting layer 506 to emit light. Therefore, one lower electrode 504 and partial regions of the light emitting layer 506 and the upper electrode 508 corresponding to this lower electrode 504 compose one light emitting element 602. That is to say, in the present embodiment, the light emitting substrate 402 includes a plurality of light emitting elements 602.

For example, an organic EL film can be used in the light emitting layer 506. The upper electrode 508 is composed of, for example, a transparent electrode made of indium tin oxide (ITO) or the like so as to allow the light emission wavelength of the light emitting layer 506 to be transmitted therethrough. Note that although the entirety of the upper electrode 508 allows the light emission wavelength of the light emitting layer 506 to be transmitted therethrough in the present embodiment, it is not necessary for the entirety of the upper electrode 508 to allow the light emission wavelength to be transmitted therethrough. Specifically, it is sufficient that the light emission wavelength be transmitted therethrough the partial regions through which the light from each light emitting element 602 passes. Note that although one continuous light emitting layer 506 is formed in FIG. 6, a plurality of light emitting layers 506 that each have a width equal to the width W of the lower electrodes 504 may be respectively formed on the lower electrodes 504. Also, although the upper electrode 508 is one common electrode for the plurality of lower electrodes 504 in FIG. 6, a plurality of upper electrodes 508 that each have a width equal to the width W of the lower electrodes 504 may be formed in correspondence with the lower electrodes 504, respectively. Furthermore, among the lower electrodes 504 in each light emitting chip 400, a first plurality of lower electrodes 504 may be covered with a first light emitting layer 506, and a second plurality of lower electrodes 504 may be covered with a second light emitting layer 506. Moreover, in each light emitting chip 400, a first upper electrode 508 and a second upper electrode 508 may be formed commonly in correspondence with a first plurality of lower electrodes 504 and a second plurality of lower electrodes 504, respectively, among the lower electrodes 504. In these configurations, too, one lower electrode 504 and regions of the light emitting layer 506 and the upper electrode 508 corresponding to this lower electrode 504 compose one light emitting element 602.

FIG. 7 is a circuit diagram related to a control configuration for controlling the light emitting chips 400. The image controller 700 is a control circuit that communicates with the printed substrate 202 via a plurality of signal lines (wires). The image controller 700 includes a CPU 701, a clock generation unit 702, an image data processing unit 703, a register access unit 704, and a light emission control unit 705. The light emission control unit 705 is a constituent element that composes an exposure apparatus together with the exposure head 106. The light emission control unit 705 terminates the signal lines between itself and the printed substrate 202. The n^{th} light emitting chip 400-n (n is an integer from 1 to 20) on the printed substrate 202 is connected to the light emission control unit 705 via a signal line DATAn and a signal line WRITEn. The signal line DATAn is used to transmit image data from the image controller 700 to the light emitting chip 400-n. The signal line WRITEn is used by the image controller 700 to write control data to a register in the light emitting chip 400-n.

Furthermore, one signal line CLK, one signal line SYNC, and one signal line EN are provided between the light emission control unit 705 and each light emitting chip 400. The signal line CLK is used to transmit a clock signal that is intended for data transmission via the signal lines DATAn and WRITEn. The light emission control unit 705 outputs, to the signal line CLK, a clock signal that has been generated based on a reference clock signal from the clock generation unit 702. Signals transmitted to the signal line SYNC and the signal line EN will be described later.

The CPU 701 controls the entirety of the image forming apparatus 1. The image data processing unit 703 generates image data in a binary bitmap format for controlling ON and OFF of light emission of the light emitting elements 602 in the light emitting chips 400 on the printed substrate 202 by executing image processing with respect to image data received from the read unit 100 or an external apparatus. This image processing can include, for example, raster conversion, tone correction, color conversion, and halftone processing. The image data processing unit 703 transmits the generated image data to the light emission control unit 705 as input image data. The register access unit 704 receives control data to be written to the registers inside the respective light emitting chips 400 from the CPU 701, and transmits the control data to the light emission control unit 705.

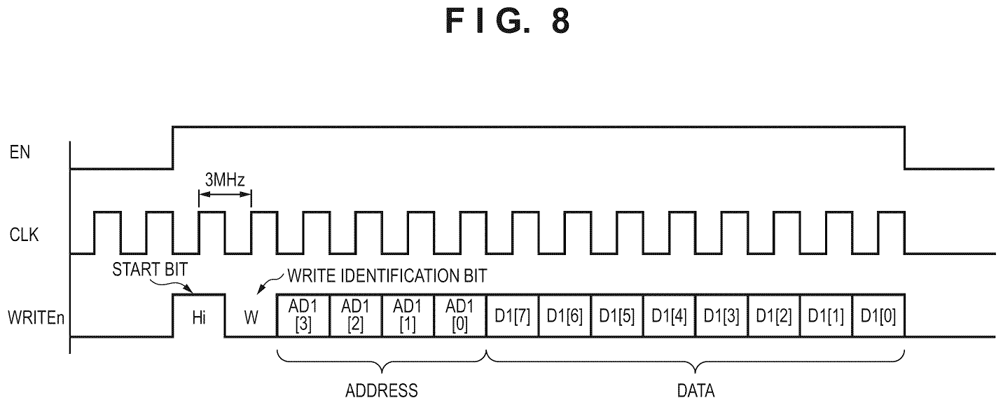

FIG. 8 shows transitions in signal levels of the respective signal lines in a case where control data is written to a register in a light emitting chip 400. An enable signal that reaches a high level and indicates that communication is currently performed during communication is output to the signal line EN. In synchronization with rising of the enable signal, the light emission control unit 705 transmits a start bit to the signal line WRITEn. Subsequently, the light emission control unit 705 transmits a write identification bit indicating a writing operation, and then transmits an address (4 bits in the present example) of the register to which the control data is to be written, and the control data (8 bits in the present example). During the writing to the register, the light emission control unit 705 sets the frequency of the clock signal to be transmitted to the signal line CLK at 3 MHz, for example.

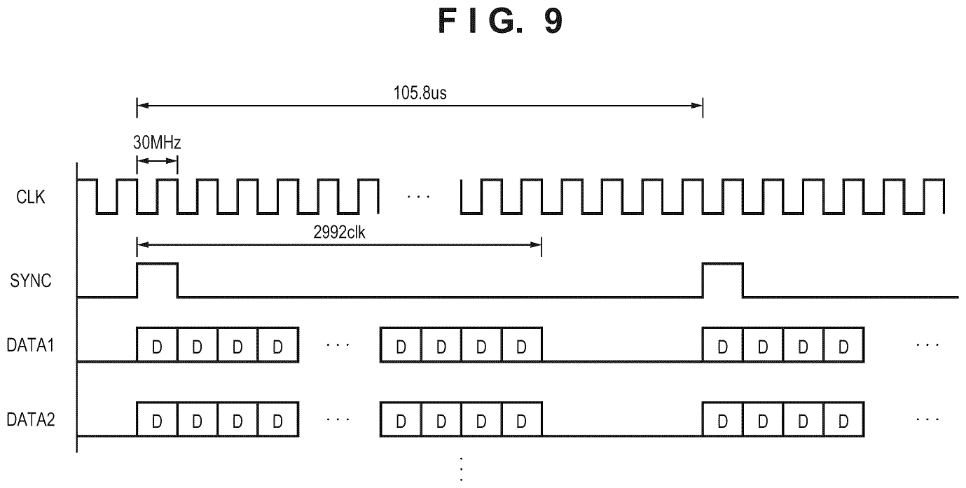

FIG. 9 shows transitions in signal levels of the respective signal lines in a case where image data is transmitted to each light emitting chip 400. A cyclic line synchronization signal indicating an exposure timing for each line of a photosensitive member 102 is output to the signal line SYNC. Provided that the circumferential velocity of the photosensitive member 102 is 200 mm/s and the resolution in the circumferential direction is 1200 dpi (approximately 21.16 μm), the line synchronization signal is output in a cycle of approximately 105.8 us. In synchronization with rising of the line synchronization signal, the light emission control unit 705 transmits image data to the signal lines DATA1 to DATA20. In the present embodiment, as each light emitting chip 400 includes 2992 light emitting elements 602, it is necessary to transmit, to each light emitting chip 400, image data that indicates light emission and non-light emission of each of the total of 2992 light emitting elements 602 within the cycle of approximately 105.8 μs. For this reason, in the present example, when transmitting image data, the light emission control unit 705 sets the frequency of the clock signal transmitted to the signal line CLK at 30 MHz as shown in FIG. 9.

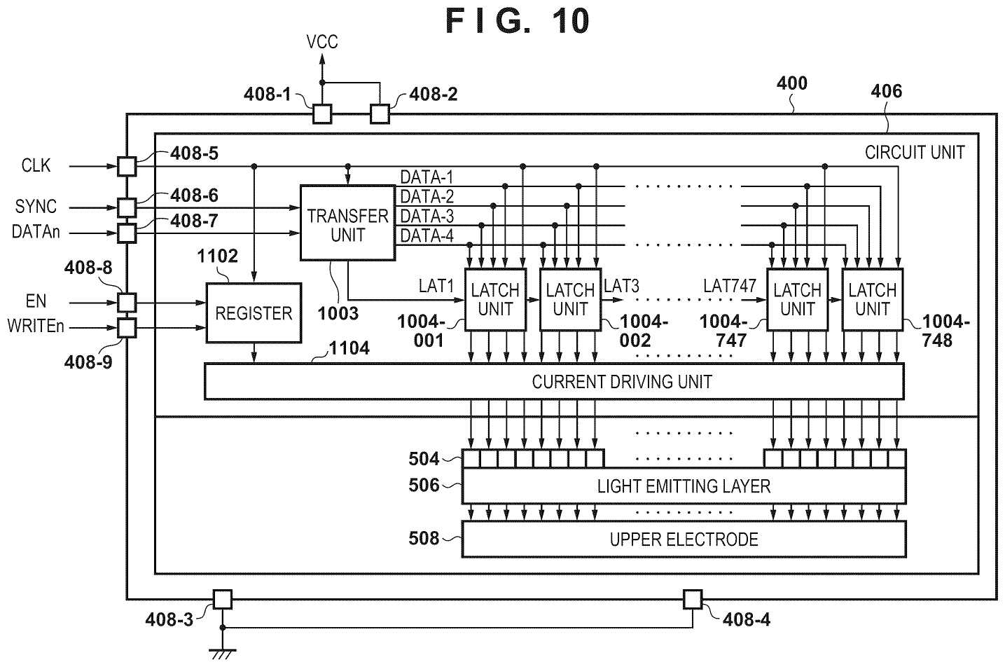

FIG. 10 is a functional block diagram showing a detailed configuration of one light emitting chip 400 (the n^{th} light emitting chip 400-n). As shown in FIG. 5 also, the light emitting chip 400 includes nine pads 408-1 to 408-9. The pad 408-1 and the pad 408-2 are connected to a power source voltage VCC via power source lines. This power source voltage VCC supplies power to each circuit in the circuit unit 406 of the light emitting chip 400. The pad 408-3 and the pad 408-4 are connected to the ground via ground lines. Each circuit in the circuit unit 406 and the upper electrode 508 are connected to the ground via the pad 408-3 and the pad 408-4. The signal line CLK is connected to a transfer unit 1003, a register 1102, and latch units 1004-001 to -748 via the pad 408-5. The signal lines SYNC and DATAn are connected to the transfer unit 1003 via the pads 408-6 and 408-7. The signal lines EN and WRITEn are connected to the register 1102 via the pads 408-8 and 408-9. The register 1102 stores, for example, control data indicating a desired intensity of light emission of the light emitting elements 602.

Upon receiving a line synchronization signal from the signal line SYNC, the transfer unit 1003 receives, from the signal line DATAn, input image data including a sequence of pixel values that each indicate light emission or non-light emission of one light emitting element 602, in synchronization with a clock signal from the signal line CLK. The transfer unit 1003 performs serial-parallel conversion with respect to the sequence of pixel values that are serially received from the signal line DATAn in units of M pixel values (e.g., M=4). For example, the transfer unit 1003 includes four D flip-flops that have been connected in cascade, parallelizes pixel values DATA-1, DATA-2, DATA-3, and DATA-4 that are input over four clocks, and outputs the resultant pixel values to the latch units 1004-0001 to 1004-748. Also, the transfer unit 1003 further includes four D flip-flops for delaying the line synchronization signal, and outputs a first latch signal to the latch unit 1004-001 via a signal line LAT1 at a timing that is four clocks behind the inputting of the line synchronization signal.

The kth latch unit 1004-k (k is an integer from 1 to 748) causes a latch circuit to hold the four pixel values DATA-1, DATA-2, DATA-3, and DATA-4, which are input from the transfer unit 1003 at the same time as inputting of the kth latch signal. Furthermore, except for the latch unit 1004-748 in the last stage, the kth latch unit 1004-k delays the kth latch signal by four clocks, and outputs the (k+1)th latch signal to the latch unit 1004-(k+1) via the signal line LAT (k+1). Then, during a signal cycle of the kth latch signal, the kth latch unit 1004-k keeps outputting a driving signal based on the four pixel values held by the latch circuit to a current driving unit 1104. For example, there is a delay corresponding to four clocks between the timing at which the first latch signal is input to the latch unit 1004-1 and the timing at which a second latch signal is input to the latch unit 1004-2. Therefore, the latch unit 1004-1 outputs a driving signal based on the first, second, third, and fourth pixel values to the current driving unit 1104, whereas the latch unit 1004-2 outputs a driving signal based on the fifth, sixth, seventh, and eighth pixel values to the current driving unit 1104. In sum, the latch unit 1004-k outputs a driving signal based on the (4k−3)^{th}, (4k−2)^{th}, (4k−1)^{th}, and (4k)^{th} pixel values to the current driving unit 1104. Therefore, according to the embodiment shown in FIG. 10, the 748 latch units 1004-001 to 1004-748 output the 2992 driving signals for controlling driving of the 2992 (=748×4) light emitting elements 602 to the current driving unit 1104 substantially in parallel. Each driving signal is a binary signal indicating a high level or a low level.

The current driving unit 1104 includes 2992 light emission driving circuits that respectively correspond to the 2992 light emitting elements 602 that respectively include the partial regions of the light emitting layer 506. While the corresponding driving signal indicates a high level, which means light emission ON, each light emission driving circuit applies a driving voltage corresponding to the intensity of light emission indicated by the control data inside the register 1102 to the light emitting layer 506 of the corresponding light emitting element 602. As a result, a current flows to the light emitting layer 506, and the light emitting element 602 emits light. Note that the control data may indicate one individual intensity of light emission for each light emitting element 602, may indicate one intensity of light emission for each group of light emitting elements 602, or may indicate one common intensity of light emission for all of the light emitting elements 602.

### 3. CONTROL ON MULTIPLE EXPOSURE

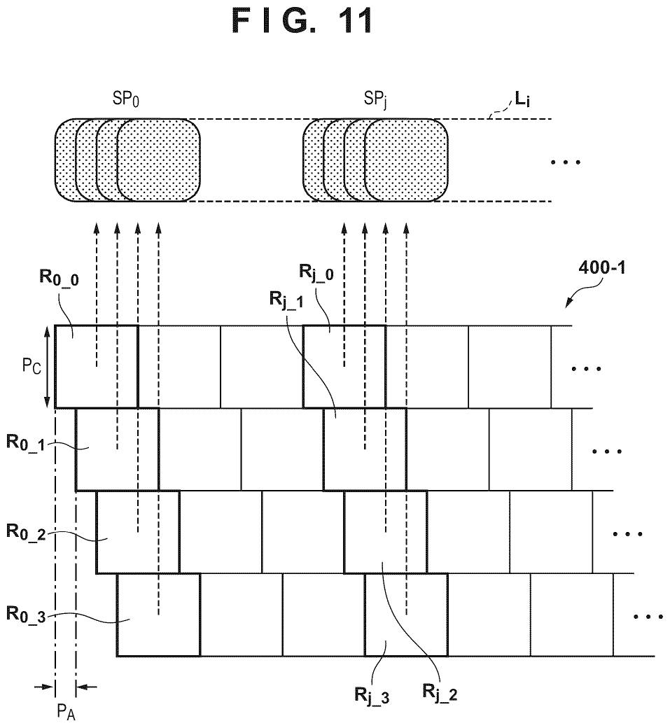

FIG. 4 shows an example in which the light emitting elements 602 are arrayed in a complete grid-like pattern in each light emitting chip 400; however, in reality, M light emitting elements 602 in each row can be arrayed in a staircase pattern at a constant pitch in the present embodiment. FIG. 11 is a diagram illustrating multiple exposure performed by the light emitting elements that are arrayed in a staircase pattern. Here, an exemplary arrangement of light emitting elements in the light emitting chip 400-1 in the case of M=4 is partially shown. In the figure, R_{j_m} (j={0, 1, . . . , J−1}, m={0, 1, 2, 3} denotes a light emitting element 602 in the j^{th} column from the left in the axial direction, and the mth row from the top in the circumferential direction. The pitch Pc of the light emitting elements in the circumferential direction may be approximately 21.16 μm as stated earlier. An interval in the axial direction between two neighboring light emitting elements among M light emitting elements in each column, that is to say, a pitch PA of the light emitting elements in the axial direction, may be approximately 5 μm that corresponds to a resolution of 4800 dpi.

When the four light emitting elements in each column are arrayed in a staircase pattern in the foregoing manner, any two neighboring light emitting elements among these four light emitting elements occupy ranges that partially overlap in the axial direction. Also, the four light emitting elements in a column corresponding to each pixel position of the input image data emit light successively while the photosensitive member 102 is rotating, thereby forming a spot corresponding to the pixel position on the surface of the photosensitive member 102. In the example of FIG. 11, in a case where the leftmost pixel value in the i^{th} line in the input image data indicates light emission ON, the light emitting elements R_{0_0}, R_{0_1}, R_{0_2}, and R_{0_3} emit light successively at timings when they oppose the line Lᵢ on the surface of the photosensitive member 102, respectively. As a result, multiple exposure is performed on the leftmost spot region in the line Lᵢ, and a corresponding spot SP₀ is formed. Similarly, in a case where the j^{th} pixel value from the left in the i^{th} line in the input image data indicates light emission ON, the light emitting elements R_{j_0}, R_{j_1}, R_{j_2}, and R_{j_3} emit light successively at timings when they oppose the line Lᵢ on the surface of the photosensitive member 102, respectively. As a result, multiple exposure is performed on the j^{th} spot region from the left in the line Lᵢ, and a corresponding spot SPⱼ is formed.

As can be understood from FIG. 11, in the present embodiment, the light emitting elements in two columns that neighbor each other in the axial direction also occupy ranges that partially overlap in the axial direction. Similarly, in two light emitting chips 400 that neighbor each other in the axial direction, the light emitting elements in the rightmost column in the light emitting chip 400 on the left and the light emitting elements in the leftmost column in the light emitting chip 400 on the right also occupy ranges that partially overlap in the axial direction. Throughout the entirety of the twenty light emitting chips 400, the light emitting elements have a constant pitch P_{A} of approximately 5 μm in the axial direction. In these light emitting chips 400, the four light emitting elements in each column emit light successively at appropriate timings; consequently, a line of a smooth electrostatic latent image made up of a sequence of spots that have a constant spot interval and partially overlap one another can be formed on the surface of the photosensitive member 102. Then, such a line is formed continuously in the circumferential direction; as a result, a two-dimensional electrostatic latent image is generated.

### 4. PRODUCTION OF LIGHT EMITTING CHIPS

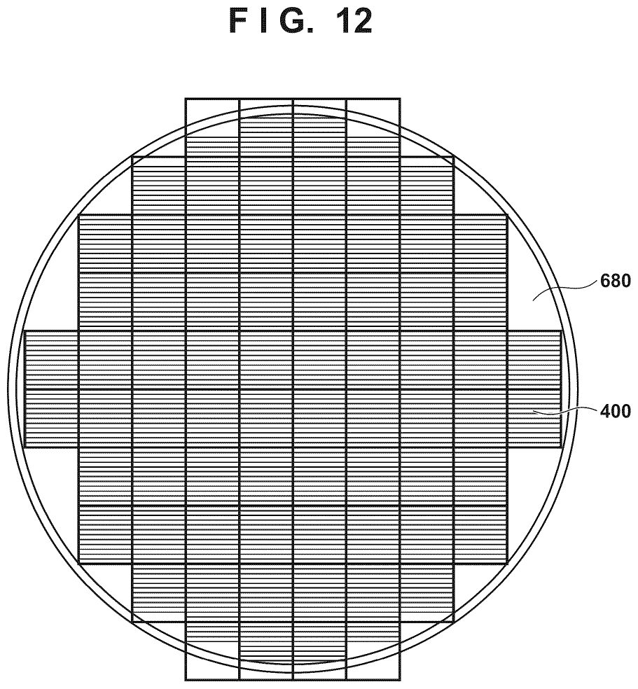

Next, a process of production of light emitting chips 400 will be described. FIG. 12 is a plan view of light emitting chips 400 mapped on a Si wafer. First, by using a known semiconductor production process, a plurality of light emitting chips 400 that each include a light emitting element array composed of a plurality of light emitting elements 602 and driving circuits is formed on a wafer 680. The plurality of light emitting elements 602 is examples of a plurality of light emitting units that emits light to which a photosensitive member is exposed. The light emitting elements 602 may be organic electro-luminescence (EL) elements. The known semiconductor production process may be, for example, a vapor phase epitaxy (VPE) method, a chemical vapor deposition (CVD) method, a molecular beam epitaxy (MBE) method, a metal organic chemical vapor deposition (MOCVD) method, or the like.

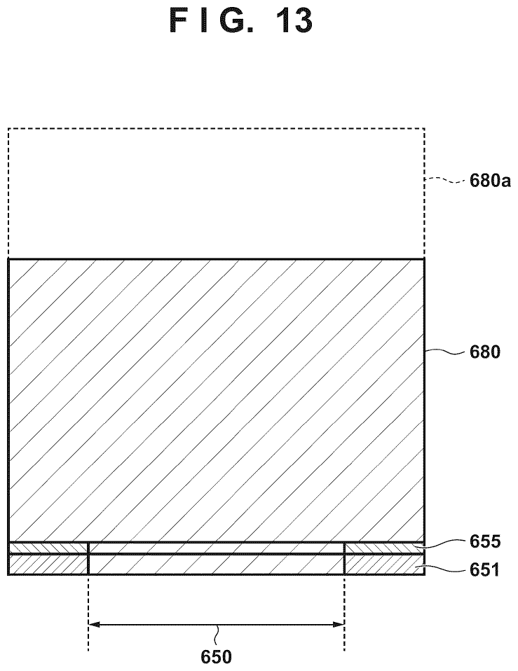

Next, a wafer thinning process will be described. FIG. 13 is a cross-sectional view illustrating the wafer thinning process. A plurality of light emitting chip regions 651, on which the light emitting chips 400 have been formed, and driving circuit regions 655 has been formed on the front surface of the wafer 680 through the above-described semiconductor production process. A scribing region 650 is formed between neighboring light emitting chip regions 651 so as to dice the wafer 680 in a later dicing process. In other words, the plurality of light emitting chip regions 651 is formed on the front surface of the wafer 680 with a scribing region 650 acting as a spacing thereamong. In the thinning process that is performed after the plurality of light emitting chips 400 is formed, a portion 680a of the wafer 680 is removed by grinding the back surface of the wafer 680, which is the opposite side of the front surface thereof, thereby thinning the wafer 680. The front surface of the wafer 680 is an example of a first surface, and the back surface of the wafer 680 is an example of a second surface.

Here, a wafer thickness in a semiconductor is generally standardized in accordance with a wafer diameter. A wafer with a diameter of 6 inches has a thickness of 625 μm, a wafer with a diameter of 8 inches has a thickness of 725 μm, and so forth. If a wafer is processed while it still has the standardized thickness, a large laser output is required, which consequently requires enlargement of the scribing region. In view of this, in the present embodiment, the thickness of the wafer 680 is reduced by the thinning process, thereby suppressing the laser output intended to form modified layers, and reducing the diameter of laser light.

In the present embodiment, a grinding process is applied to the back surface, which is the opposite side of the front surface of the wafer 680 on which the light emitting chip regions 651 are formed. This reduces the thickness of the wafer 680. Note that the smaller the thickness of the wafer, the more the advantage where the laser output intended to form the modified layers can be suppressed and the number of the modified layers necessary for dicing can be reduced. On the other hand, if the wafer 680 is excessively thinned, the strength of the wafer 680 and the strength of chips that have been cut out as the light emitting chips 400 are also reduced; for this reason, it is necessary to secure a certain extent of thickness in the wafer 680. In the present embodiment, grinding is performed so that the wafer 680 in a semiconductor after the thinning process has a thickness of 400 μm, for example.

Next, a description is given of an overview of a forming process and a dicing process for cutting out individual light emitting chips 400 from the wafer 680. In the forming process, laser light is projected toward a scribing region from the back surface of the wafer 680 so that the laser light is focused inside the wafer 680. Consequently, a modified layer is formed inside the wafer 680. The modified layer is a portion in which the wafer 680 has been partially melted, and a portion that has a lower strength and is more prone to cracks than other portions. This forming process to form a modified layer is performed multiple times at different positions of the wafer 680 in the thickness direction. Consequently, modified layers are formed at a plurality of different positions of the wafer 680 in the thickness direction. Furthermore, the forming process to form a modified layer is performed multiple times along a scribing region formed between neighboring light emitting chips 400; as a result, the modified layer is formed across the entire length of the scribing region. Thereafter, in the dicing process (also referred to as an expansion process), the wafer 680 is diced along the modified layers in the scribing region (stealth dicing), which causes the individual light emitting chips 400 to be separated along the scribing region and cut out from the wafer 680.

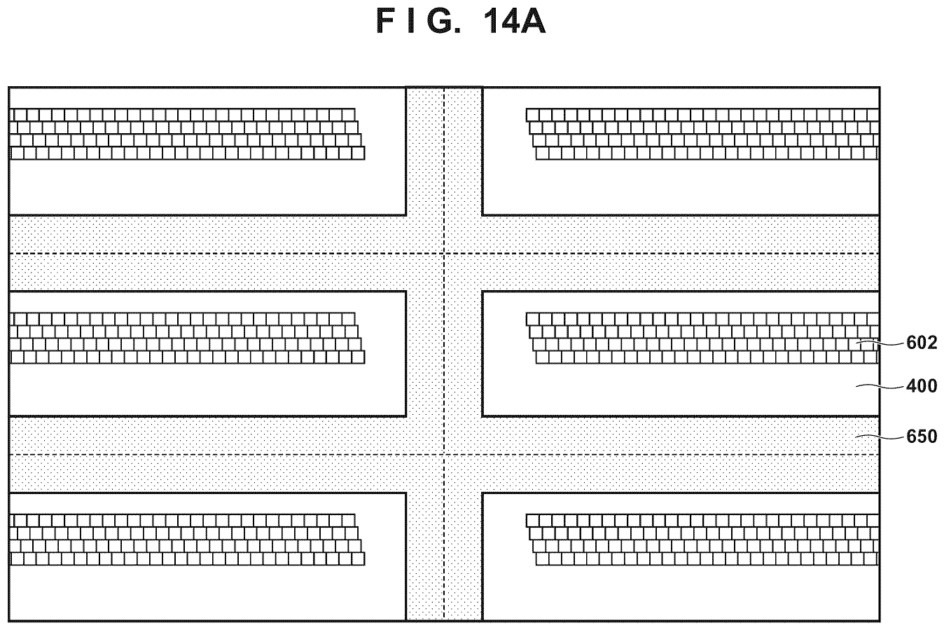

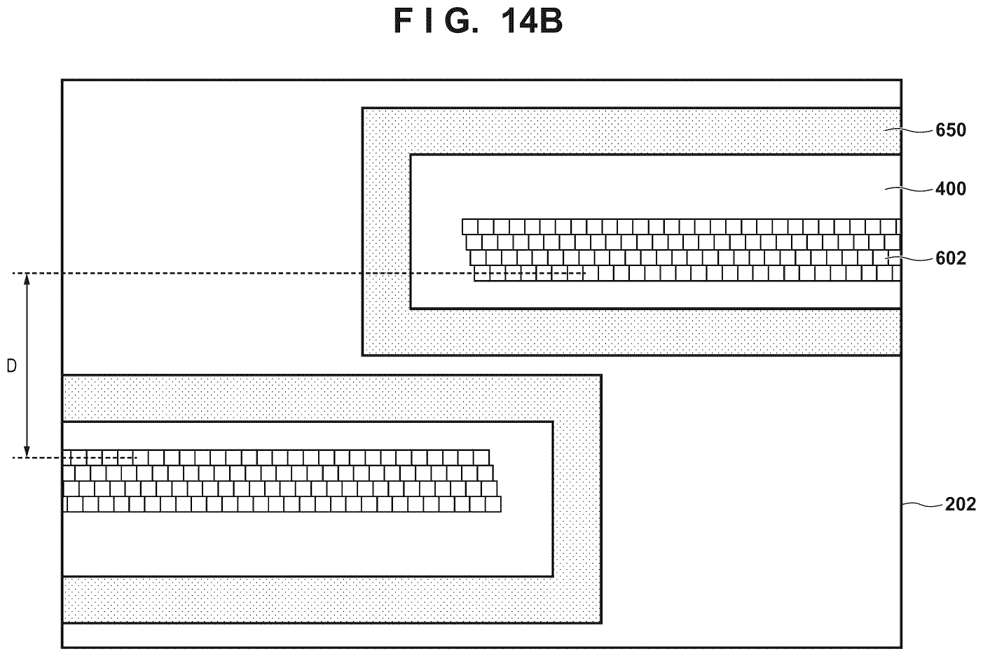

FIG. 14A is an enlarged view of light emitting chips 400 mapped on the wafer 680. A plurality of light emitting chips 400 is arrayed in a matrix to be at an equal interval in two directions. A longitudinal direction of the light emitting chips 400 is an example of a predetermined direction. A scribing region 650 is formed between neighboring light emitting chips 400. In a dicing process, the wafer 680 is diced along this scribing region. This makes the light emitting chips 400 separated, thereby cutting out the individual light emitting chips 400.

Dot lines shown in FIG. 14A are lines that run on the centers of the belt-like scribing region 650. The lines on the centers of the scribing region 650 are also referred to as scribing lines along which cutting is performed. Normally, the width of the scribing region 650 is set so as to achieve a sufficient cutting accuracy of a dicing apparatus and a sufficient spread angle of the laser light. In the wafer 680, a portion exposed to the laser light, and the vicinity of the position on which the energy is concentrated when a modified layer is formed by focusing the laser light, have high temperatures. For this reason, a modified layer is normally formed by projecting the laser light onto a position that is at a sufficient distance from the light emitting elements 602 and control circuits of the light emitting chips 400. If the laser light causes damage to the light emitting chips 400, the light emitting elements 602 or control circuits inside the light emitting chips 400 are destroyed, and the light emitting elements 602 do not emit light even if control signals are transmitted.

FIG. 14B is a diagram of light emitting chips 400 arranged on the printed substrate 202, which have been cut out from the wafer 680 by dicing the wafer 680 after forming the modified layers by projecting the laser light along the dot lines of FIG. 14A. The scribing region 650 is present around the outer periphery of each light emitting chip 400 that has been separated. Here, a distance D between the light emitting elements 602 in the light emitting chip 400 in the first column and the light emitting elements 602 in the light emitting chip 400 in the second column encompasses the scribing region 650, too. In view of this, it is desirable that the scribing region 650 between neighboring light emitting chips 400 be as small as possible for the sake of the light take-up efficiency of the rod lens array.

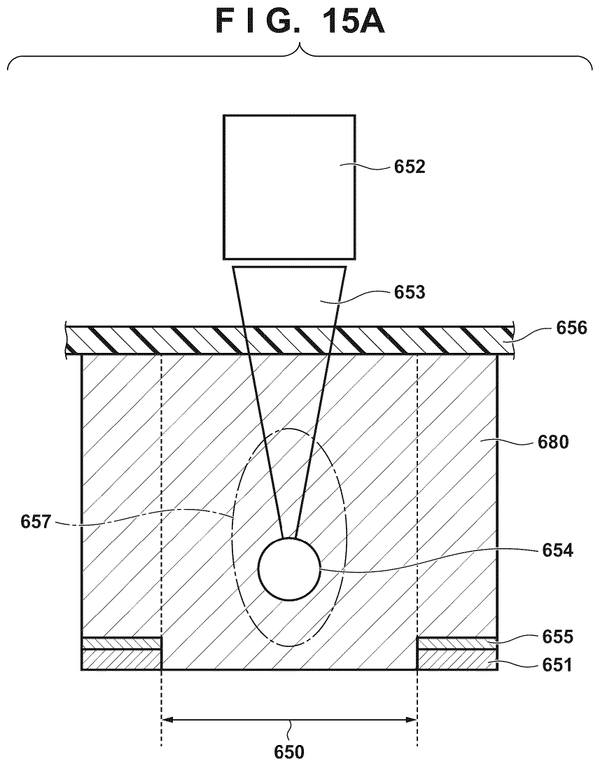

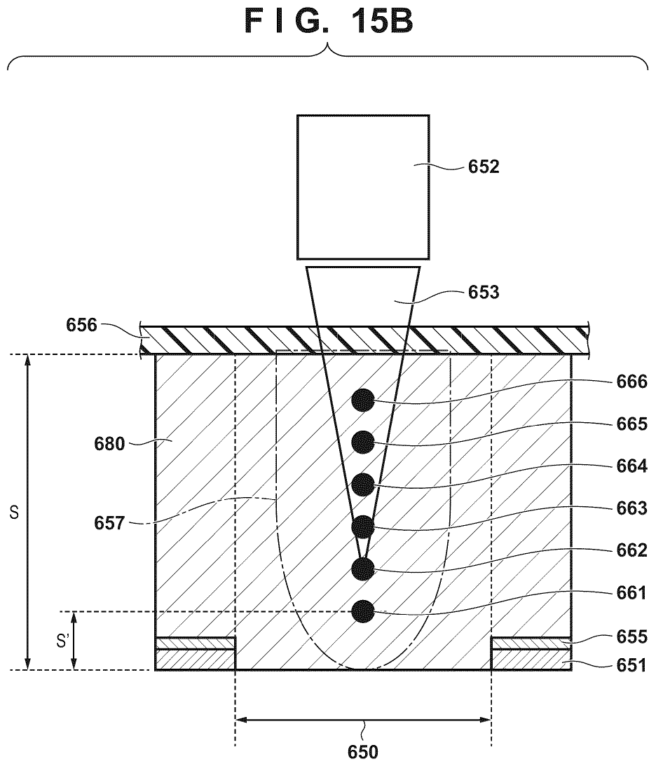

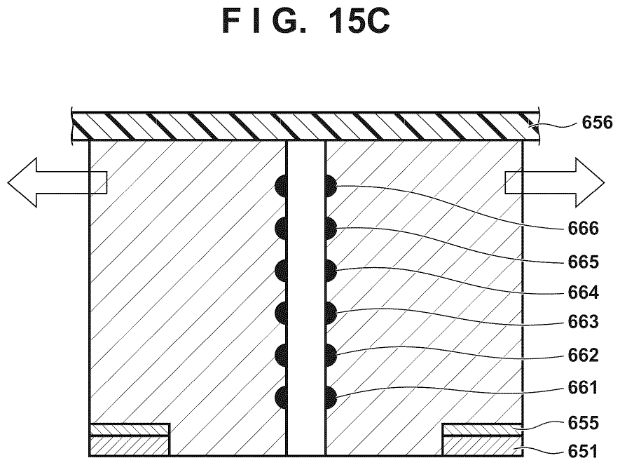

FIG. 15A and FIG. 15B are diagrams illustrating the forming process to form a modified layer using incident laser light (a stealth dicing process). FIG. 15A shows how the laser light is made incident in the forming process in a cross-section of the wafer 680. A scribing region 650 is present between neighboring light emitting chips 400. Laser light 653 is projected from a laser light source 652, and is made incident from the back surface of the wafer 680. The laser light 653 is focused in the scribing region 650 inside the wafer 680. The laser light source 652 is, for example, a pulsed laser.

In the present working example, a dicing tape 656 is pasted on the back surface of the wafer 680, which is the opposite side of the front surface on which the light emitting chips 400 are formed, so as to fix the wafer 680 in position. The laser light 653 is made incident from the back surface of the wafer 680 via the dicing tape. The advantage of back-surface incidence is that, because the light emitting chip regions 651 and the driving circuit regions 655 do not exist on the optical path of the laser light 653, the risk of the light emitting elements 602 and the driving circuit regions 655 being damage by the projection of the laser light can be lowered. Therefore, in the case of back-surface incidence, the wafer 680 can be cut by projecting the laser light 653 onto regions close to the edges of the light emitting chips 400 compared to conventional cases where a larger scribing region needs to be secured.

A point on which the laser light is focused in the scribing region 650 inside the wafer 680 is called a light focus point 654. The vicinity of the light focus point 654 has a high temperature due to the energy of the laser light 653 during formation of a modified layer even if it is distanced from the optical path of the laser light 653, and is therefore damaged by heat. A heat damage region 657 indicated by an elliptic dash-dot line in FIG. 15A is a region damaged by heat when a modified layer is formed at the light focus point 654. Therefore, it is preferred that the light focus point 654 be distanced from the light emitting chip regions 651. In the present embodiment, the laser light 653 is focused on a position that is distanced from the front surface of the wafer 680 by at least 30 μm in the thickness direction of the wafer 680. Note that the laser light 653 is focused on a position within 100 μm from the front surface of the wafer 680 in the thickness direction of the wafer 680. Note that the position of the light focus point 654 of the laser light 653 is not limited in particular. Furthermore, as the heat damage region 657 increases in proportion to the laser output, the damage caused by heat can be alleviated by reducing the heat damage region 657 with a weakened laser output. It is effective to extend a time period of laser processing, or reduce the thickness of the wafer 680, to weaken the laser output. In the present embodiment, the laser light 653 is projected after reducing the thickness of the wafer 680 by applying grinding processing to the back surface of the wafer 680 (back grinding); therefore, the laser output is suppressed, and the region of projection of the laser light 653 and the range of the heat damage region 657 are reduced.

FIG. 15B is a diagram showing an image of six modified layers formed along the depth direction of the wafer 680. By projecting the laser light 653 multiple times while shifting the position of the light focus point 654 of the laser light 653 in the thickness direction of the wafer 680, a plurality of modified layers is formed at positions that are on the same cross-section but differ from one another in the thickness direction of the wafer 680.

The modified layers are formed in order from a deep section as viewed from the surface of incidence of the laser light 653. When the deepest first modified layer (a modified layer closest to the light emitting chip regions 651) is formed, there is a risk that the heat-caused damage be given if the distance to the light emitting chip regions 651 is short; thus, it is necessary to determine the position of the first modified layer 661 in the thickness direction so as not to give the heat-caused damage. Here, the first modified layer 661 is formed at a position that is distanced from the front surface by 30 μm or more (i.e., a distance S′ from the front surface in the thickness direction ≥30 μm). Also, as a smaller thickness (distance S) of the wafer 680 can achieve a weaker laser output, it is advantageous for the wafer 680 to be thin in a case where the scribing region 650 is to be reduced. In the example presented here, the thinned wafer 680 has a thickness of 400 μm, and six modified layers are formed. After the first modified layer 661 has been formed, the second modified layer 662, the third modified layer 663, the fourth modified layer 664, the fifth modified layer 665, and the sixth modified layer 666 are formed in order by shifting the light focus point 654 of the laser light 653 toward the back surface on which the dicing tape 656 is pasted. Here, the first modified layer 661 to the sixth modified layer 666 are formed by changing the position of the light focus point 654 of the laser light 653 in the thickness direction, without moving the laser light source 652 in the planar direction of the wafer 680. Note that the position of the light focus point 654 of the laser light 653 may be moved by moving the position of a lens for focusing the laser light 653 in the thickness direction of the wafer 680, or may be moved by moving the laser light source 652 in the thickness direction of the wafer 680. In this way, the first modified layer 661 to the sixth modified layer 666 are formed at the same position in a in a plan view, but different positions in the thickness direction of the wafer 680. Thereafter, the laser light source 652 is moved along the scribing region 650; consequently, a plurality of sets of the first modified layer 661 to the sixth modified layer 666 is formed in such a manner that they are arrayed along the scribing region. Once the sets of the first modified layer 661 to the sixth modified layer 666 have been formed along the entire scribing region 650, the forming process ends, and processing proceeds to the dicing process (expansion process).

FIG. 15C is a diagram illustrating the dicing process in which the wafer is diced along the modified layers into light emitting chips. In the dicing process, the wafer 680 is pulled toward the outer circumference. As a result, the plurality of modified layers is joined together along the thickness direction of the wafer 680 and the scribing lines, the scribing region 650 is cracked, and the wafer 680 is diced as shown in FIG. 15C. Accordingly, the individual light emitting chips 400 are separated and cut out.

As described above, in the present embodiment, the light emitting chips 400 are cut out through stealth dicing where the laser light is made incident from the back surface of the wafer 680 that has been thinned in the thinning process; in this way, the laser output can be suppressed, and the heat-caused damage in the vicinity of the light focus point 654 can be alleviated.

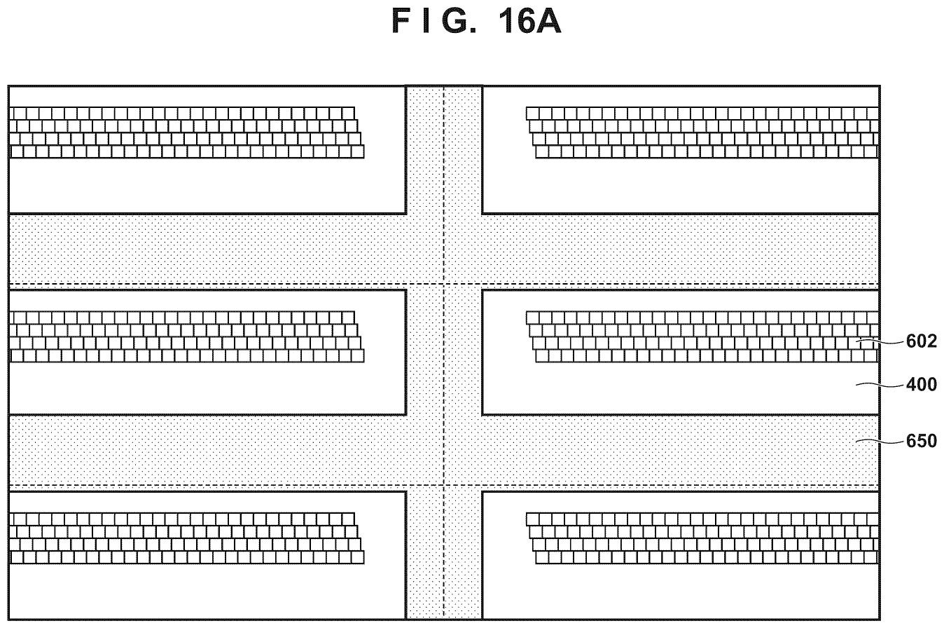

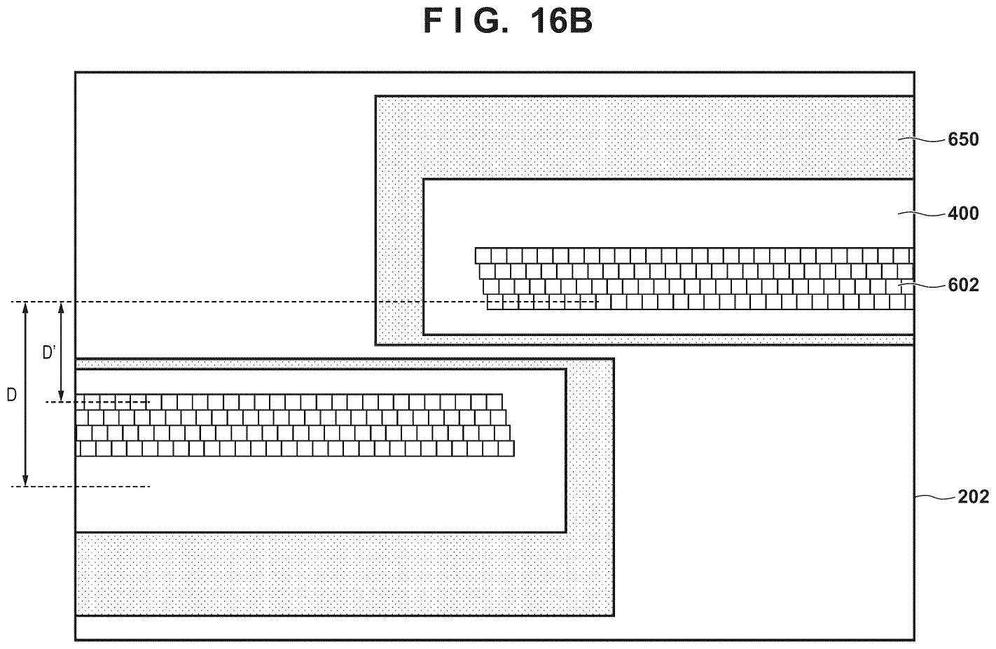

In one modification example, the position of the first modified layer may be distanced from the front surface on which the light emitting chips 400 are formed by 30 μm, the scribing lines may be set at positions that are closer to the edges of the scribing region 650 than to the centers thereof, and the wafer may be diced along these scribing lines. FIG. 16A and FIG. 16B are diagrams illustrating the modification example. FIG. 16A is an enlarged plan view of light emitting chips mapped on the wafer in the modification example. FIG. 16B is a plan view showing a state where the light emitting chips that have been cut out from the wafer in the modification example have been arranged on the printed substrate. In FIG. 16A, the scribing lines indicated by dot lines are set at positions that are closer to the edges of the scribing region 650 than to the centers thereof. The wafer is diced along these scribing lines, the light emitting chips 400 are cut out, and the light emitting chips 400 are arranged on the printed substrate 202 in a zig-zag manner; as a result, the light emitting elements 602 in the light emitting chips 400 in the first column and the second column can be brought in proximity to each other as shown in FIG. 16B. Assuming that the scribing region has a width of 100 μm, in a conventional case where the wafer is diced along the centers of the scribing region, the scribing region 650 of 50 μm remains around the outer peripheries of the light emitting chips 400; on the other hand, in a case where the foregoing method is used, the remaining scribing region 650 can be 10 μm. These scribing lines can shorten the distance between the light emitting elements 602 in neighboring light emitting chips 400 by 80 μm (the portion corresponding to the difference between D and D′ in the figure) compared to the conventional scribing lines.

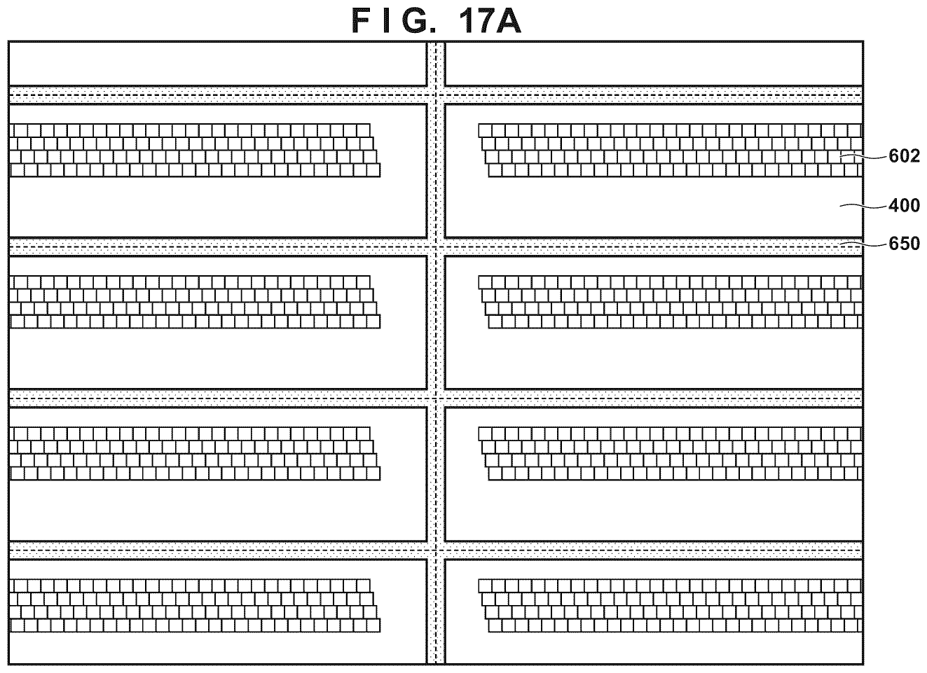

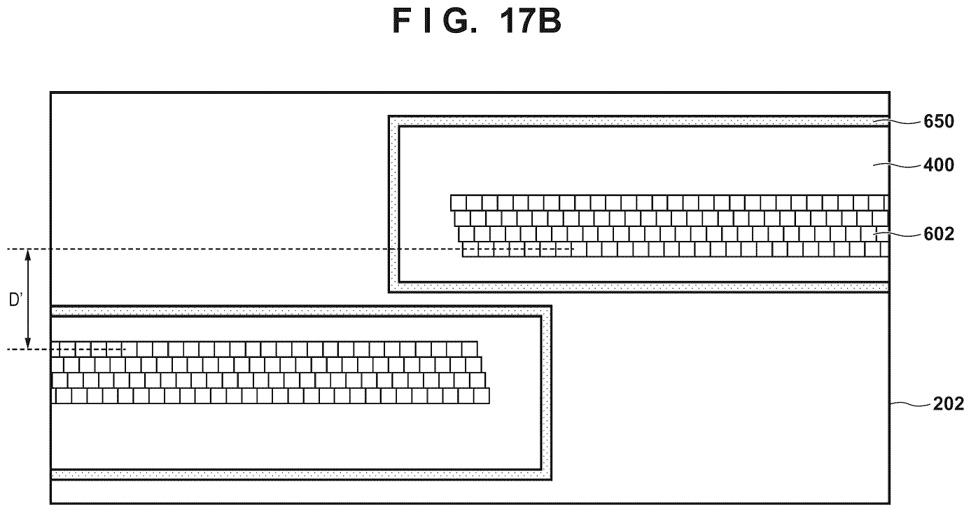

FIG. 17A is an enlarged plan view of light emitting chips 400 mapped on the wafer 680 according to another modification example. FIG. 17B is a plan view showing a state where the light emitting chips 400 that have been cut out from the wafer 680 in another modification example have been arranged on the printed substrate 202. In another modification example shown in FIG. 17A, the scribing region 650 around the outer peripheries of the light emitting chips 400 has been reduced. Such mapping can increase the number of light emitting chips 400 that can be produced from one wafer 680, and thus has the advantage of suppressing the cost of materials.

The light emitting chips 400 with the reduced scribing region 650 according to the modification example are arranged on the printed substrate 202 in a zig-zag manner as shown in FIG. 17B. By reducing the scribing region 650 around the outer peripheries of the light emitting chips 400 as in the present modification example, the light emitting elements 602 in the light emitting chip 400 in the first column and the light emitting chip 400 in the second column can be brought in proximity to each other when arranging the light emitting chips 400 on the printed substrate 202.

### 5. SUMMARY

As described above, in the present embodiment, the wafer 680 is thinned, the modified layers are formed by making the laser light incident from the back surface of the wafer 680 on which the light emitting chip regions 651 are not formed, and the wafer 680 is diced. In this way, the diameter of the laser light 653 can be reduced with a reduced laser output, and the scribing region can thus be reduced in the present embodiment. As a result, in the present embodiment, an excess portion that is not relevant to the light emitting elements 602 can be reduced around the outer peripheries of the light emitting chips 400 that have been extracted from the wafer 680. Therefore, in the present embodiment, the light emitting elements 602 in the light emitting chip 400 in the first column and the light emitting elements 602 in the light emitting chip 400 in the second column, which are arranged on the printed substrate 202 in a zig-zag manner, can be brought in proximity to each other, and the light take-up efficiency of the rod lens array 203 can be improved.

In the present embodiment, the thinning process for thinning the wafer 680 is performed after the light emitting chips 400 are formed. In this way, the light emitting chips 400 can be formed in a state where the wafer 680 is thick, and thus the wafer 680 can be protected from breakage while maintaining a sufficient strength of the wafer 680 during formation of the light emitting chips 400.

In the present embodiment, the modified layers are formed by focusing the laser light 653 on a position that is distanced from the front surface of the wafer 680 by 30 μm or more. This can suppress damage caused by heat of the laser light 653 on the light emitting chips 400 formed on the front surface of the wafer 680. The modified layers are formed by focusing the laser light 653 on a position within 100 μm from the front surface of the wafer 680. This can suppress breakage of the dicing tape 656 pasted on the back surface of the wafer 680.

In the present embodiment, a plurality of modified layers is formed at different positions in the thickness direction of the wafer 680. Accordingly, in the present embodiment, the wafer 680 can be diced more accurately along a scribing line composed of the plurality of modified layers.

In the present embodiment, as the modified layers are formed by emitting the laser light 653 via the dicing tape 656, breakage of the light emitting chips 400 caused by falling or the like can be suppressed when dicing the wafer 680.

### 6. OTHER EMBODIMENTS

The examples described in the embodiment are illustrative, and no limitation is intended by the numerical values that have been used in the description. For example, the width of the scribing region 650, the thickness of the wafer 680, the position at which the first modified layer is formed, and the like may be changed in accordance with conditions.

Although the above embodiment has been described using an example in which six modified layers are formed at different positions in the thickness direction of the wafer 680, the number of the modified layers is not particularly limited to the above-described example, and may be three or more, for example.

The present invention is not limited to the above embodiments and various changes and modifications can be made within the spirit and scope of the present invention. Therefore, to apprise the public of the scope of the present invention, the following claims are made.

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-131464, filed Aug. 10, 2023, which is hereby incorporated by reference herein in its entirety.

What is claimed is:

1. A method of production of light emitting chips to be used in an exposure head of an image forming apparatus, the method comprising:
thinning a wafer having a first surface on which a plurality of light emitting chips is formed with a scribing region acting as a spacing therebetween by grinding a second surface thereof that is a surface opposite to the first surface, each of the plurality of light emitting chips including a plurality of light emitting units that is arrayed along a predetermined direction and emit light to which a photosensitive member is exposed;
forming a modified layer inside the wafer by projecting laser light toward the scribing region from the second surface so that the laser light is focused inside the wafer; and
dicing the wafer along the modified layer in the scribing region into the light emitting chips.

2. The method of production of light emitting chips according to claim 1, wherein
the thinning of the wafer is performed after the plurality of light emitting chips is formed on the first surface.

3. The method of production of light emitting chips according to claim 1, wherein
in the forming of the modified layer, the laser light is focused on a position that is distanced from the first surface of the wafer by 30 μm or more in a thickness direction of the wafer.

4. The method of production of light emitting chips according to claim 3, wherein
in the forming of the modified layer, the laser light is focused on a position within 100 μm from the first surface of the wafer in the thickness direction of the wafer.

5. The method of production of light emitting chips according to claim 1, wherein
in the forming of the modified layer, a plurality of modified layers is formed at different positions in a thickness direction of the wafer.

6. The method of production of light emitting chips according to claim 5, wherein
in the forming of the modified layer, three or more of the modified layer are formed at different positions in the thickness direction of the wafer.

7. The method of production of light emitting chips according to claim 5, wherein
in the forming of the modified layer, the plurality of modified layers is formed by changing a position on which the laser light is focused.

8. The method of production of light emitting chips according to claim 1, wherein
in the forming of the modified layer, the modified layer is formed by projecting the laser light via a dicing tape pasted on the scribing region.

9. A light emitting chip to be used in an exposure head of an image forming apparatus, the light emitting chip being produced by
thinning a wafer having a first surface on which a plurality of light emitting chips is formed with a scribing region acting as a spacing therebetween by grinding a second surface thereof that is a surface opposite to the first surface, each of the plurality of light emitting chips including a plurality of light emitting units that is arrayed along a predetermined direction and emit light to which a photosensitive member is exposed;
forming a modified layer inside the wafer by projecting laser light toward the scribing region from the second surface so that the laser light is focused inside the wafer; and
dicing the wafer along the modified layer in the scribing region into the light emitting chips.

10. An exposure head, comprising:
a light emitting chip produced by
thinning a wafer having a first surface on which a plurality of light emitting chips is formed with a scribing region acting as a spacing therebetween by grinding a second surface thereof that is a surface opposite to the first surface, each of the plurality of light emitting chips including a plurality of light emitting units that is arrayed along a predetermined direction and emit light to which a photosensitive member is exposed,
forming a modified layer inside the wafer by projecting laser light toward the scribing region from the second surface so that the laser light is focused inside the wafer, and
dicing the wafer along the modified layer in the scribing region into the light emitting chips; and
a substrate on which the light emitting chip has been mounted.

11. An image forming apparatus, comprising:
an exposure head including
a light emitting chip produced by
thinning a wafer having a first surface on which a plurality of light emitting chips is formed with a scribing region acting as a spacing therebetween by grinding a second surface thereof that is a surface opposite to the first surface, each of the plurality of light emitting chips including a plurality of light emitting units that is arrayed along a predetermined direction and emit light to which a photosensitive member is exposed,
forming a modified layer inside the wafer by projecting laser light toward the scribing region from the second surface so that the laser light is focused inside the wafer, and
dicing the wafer along the modified layer in the scribing region into the light emitting chips, and
a substrate on which the light emitting chip has been mounted.

12. The method of production of light emitting chips according to claim 1, wherein
the plurality of light emitting units is organic EL.
